(19) United States
(12) Patent Application Publication
(10) Pub. No.: US 2023/0389277 A1
(43) Pub. Date: Nov. 30, 2023

(54) TRANSISTOR AND MANUFACTURING METHOD THEREOF, AND MEMORY

(71) Applicant: CHANGXIN MEMORY TECHNOLOGIES, INC., Hefei City (CN)

(72) Inventors: YOUMING LIU, Hefei City (CN); Deyuan Xiao, Hefei City (CN)

(21) Appl. No.: 17/816,435

(22) Filed: Aug. 1, 2022

Related U.S. Application Data
(63) Continuation of application No. PCT/CN2022/098020, filed on Jun. 10, 2022.

(30) Foreign Application Priority Data
May 31, 2022 (CN) 202210614642.5

(51) Int. Cl. H01L 27/108; H01L 29/08; H01L 29/10

(52) U.S. Cl. CPC H01L 27/10805; H01L 27/10873; H01L 29/0847; H01L 29/1033

(57) ABSTRACT

The present disclosure provides a transistor and a manufacturing method thereof, and a memory, and relates to the technical field of semiconductors. The transistor includes: a channel, wherein a plurality of accommodation spaces are formed therein; a plurality of gates, wherein the plurality of gates have a same extension direction and each have a first end and a second end that are opposite, the first end of the gate is located inside one of the accommodation spaces, and the second end of the gate is located outside the corresponding accommodation space; a dielectric layer, located between the gate and the channel, insulating and isolating the gate and the channel; a source, provided at one end of the channel; and a drain, provided at the other end of the channel, wherein the drain and the source are spaced apart.

### CROSS-REFERENCE TO RELATED APPLICATIONS

This is a continuation of International Application No. PCT/CN2022/098020, filed on Jun. 10, 2022, which claims the priority to Chinese Patent Application No. 202210614642.5, titled “TRANSISTOR AND MANUFACTURING METHOD THEREOF, AND MEMORY” and filed with the China National Intellectual Property Administration (CNIPA) on May 31, 2022. The entire contents of International Application No. PCT/CN2022/098020 and Chinese Patent Application No. 202210614642.5 are incorporated herein by reference.

### TECHNICAL FIELD

The present disclosure relates to the technical field of semiconductors, and in particular to a transistor and a manufacturing method thereof, and a memory.

### BACKGROUND

With the continuous development of science and technology, semiconductor structures, especially memories, are increasingly widely used. The memory includes a plurality of transistors, and the transistors are generally metal-oxide-semiconductor (MOS) transistors. The MOS transistor generally includes a source, a drain, a channel between the source and the drain, a gate opposite to the channel, and a dielectric layer disposed between the gate and the channel. The MOS transistor uses an electric field formed by the gate to control an amount of induced charge in the channel, to further change a state of the channel, thereby controlling a drain current. However, a drive current of the foregoing transistor is relatively small, affecting the performance of the transistor.

### SUMMARY

In view of the foregoing problem, embodiments of the present disclosure provide a transistor and a manufacturing method thereof, and a memory.

According to some embodiments, a first aspect of the present disclosure provides a transistor, including: a channel, wherein a plurality of accommodation spaces are formed therein; a plurality of gates, wherein the plurality of gates have a same extension direction and each have a first end and a second end that are opposite, a first end of the gate is located inside one of the accommodation spaces, and a second end of the gate is located outside the corresponding accommodation space; a dielectric layer, located between the gate and the channel, insulating and isolating the gate and the channel; a source, provided at one end of the channel; and a drain, provided at the other end of the channel, wherein the drain and the source are spaced apart.

According to some embodiments, a second aspect of the present disclosure provides a memory, including the transistor described above. The memory includes the transistor.

According to some embodiments, a third aspect of the present disclosure provides a method of manufacturing a transistor, including:
forming a stacked structure, wherein the stacked structure includes a first functional layer, an insulating layer, and a second functional layer that are sequentially stacked, one of the first functional layer and the second functional layer forms a source, and the other forms a drain;
forming a first filling space in the stacked structure, wherein the first filling space runs through the second functional layer and the insulating layer, and exposes the first functional layer;
forming a channel inside the first filling space, wherein the channel has a plurality of accommodation spaces;
forming a dielectric layer on a sidewall and a bottom wall of each of the accommodation spaces, wherein the dielectric layer located in each of the accommodation spaces defines a second filling space; and
forming a gate inside each of the second filling spaces, wherein a first end of the gate is located inside the second filling space, and a second end of the gate is located outside the second filling space.

### BRIEF DESCRIPTION OF THE DRAWINGS

FIG. 1 is a schematic structural diagram of a transistor according to an embodiment of the present disclosure;

FIG. 2 is a first schematic diagram of arrangement of gates of a transistor according to an embodiment of the present disclosure;

FIG. 3 is a second schematic diagram of arrangement of gates of a transistor according to an embodiment of the present disclosure;

FIG. 4 is a third schematic diagram of arrangement of gates of a transistor according to an embodiment of the present disclosure;

FIG. 5 is a fourth schematic diagram of arrangement of gates of a transistor according to an embodiment of the present disclosure;

FIG. 6 is a fifth schematic diagram of arrangement of gates of a transistor according to an embodiment of the present disclosure;

FIG. 7 is a sixth schematic diagram of arrangement of gates of a transistor according to an embodiment of the present disclosure;

FIG. 8 is a flowchart of a method of manufacturing a transistor according to an embodiment of the present disclosure;

FIG. 9 is a schematic diagram of a stacked structure according to an embodiment of the present disclosure;

FIG. 10 is a schematic diagram after a first filling space is formed according to an embodiment of the present disclosure;

FIG. 11 is a schematic diagram after an initial channel layer is formed according to an embodiment of the present disclosure;

FIG. 12 is a schematic diagram after an accommodation space is formed according to an embodiment of the present disclosure;

FIG. 13 is a schematic diagram after a dielectric layer is formed according to an embodiment of the present disclosure; and

FIG. 14 is a schematic diagram after a gate is formed according to an embodiment of the present disclosure.

### DETAILED DESCRIPTION

In the related art, there is a problem that a drive current of a transistor is relatively small. It is found by the inventor through research that the reason is that a field effect of the transistor is contributed by a single gate, and a contact area between the gate and a channel is relatively small. Consequently, a drive current is relatively small.

Embodiments of the present disclosure provide a transistor and a manufacturing method thereof, and a memory. A plurality of gates are provided inside a same channel, increasing a contact area between the gates and the channel, and potential at each position of the channel is superposition of respective potential of the plurality of gates, such that a drive current of the transistor is increased and a control capability of the gates is improved, thereby improving performance of the transistor.

In order to make the objectives, features and advantages of the embodiments of the present disclosure clearer, the technical solutions in the embodiments of the present disclosure are described clearly and completely below with reference to the drawings in the embodiments of the present disclosure. Apparently, the described embodiments are merely a part rather than all of the embodiments of the present disclosure. All other embodiments obtained by those of ordinary skill in the art based on the embodiments of the disclosure without creative efforts shall fall within the protection scope of the present disclosure.

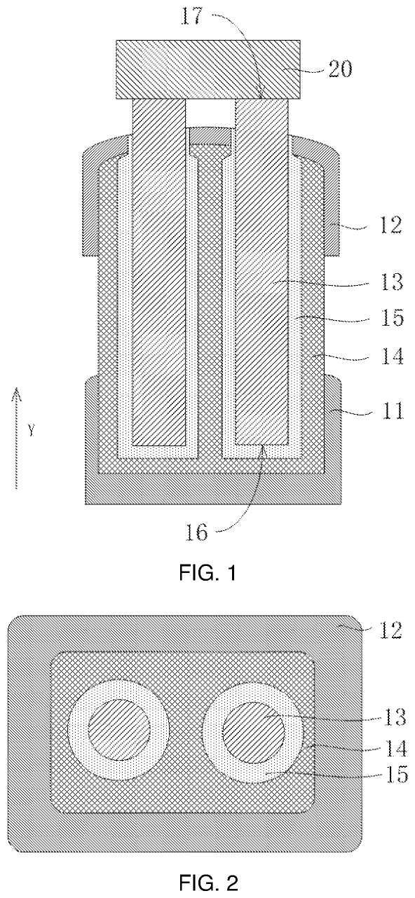

Referring to FIG. 1, FIG. 1 is a schematic structural diagram of a transistor according to an embodiment of the present disclosure. The transistor includes: a source 11, a drain 12, a channel 14, a dielectric layer 15, and a gate 13. A plurality of accommodation spaces are formed inside the channel 14, and the plurality of accommodation spaces are arranged at intervals, that is, the accommodation spaces are not in communication with each other.

A plurality of gates 13 are provided, and the plurality of gates 13 have a same extension direction, for example, the plurality of gates 13 extend along a first direction (a direction Y as shown in FIG. 1). Each of the gates 13 has a first end 16 and a second end 17 that are opposite, and the first end 16 and the second end 17 may be oppositely provided along the first direction. For example, the first end 16 of the gate 13 is a top end of the gate 13 (an upper end as shown in FIG. 1), and the second end 17 of the gate 13 is a bottom end of the gate 13 (a lower end as shown in FIG. 1). The gate 13 may be made of a metal material or a semiconductor material, for example, doped Si, doped Ge, titanium nitride (TiN), tantalum nitride (TaN), tungsten (W), titanium (Ti), tantalum (Ta), copper (Cu), aluminum (Al), gold (Au), tungsten silicide (WSi), cobalt silicide (CoSi), titanium silicide (TiSi), or a combination thereof.

Still referring to FIG. 1, along the extension direction of the gates 13, sizes of cross sections of a gate 13 located in one accommodation space are the same, that is, each gate 13 is designed to have equal cross sections, such that the gate 13 forms a column with consistent top and bottom, thereby facilitating manufacturing of the gate 13. The size of the cross section may be an area of the cross section or a diameter of the cross section.

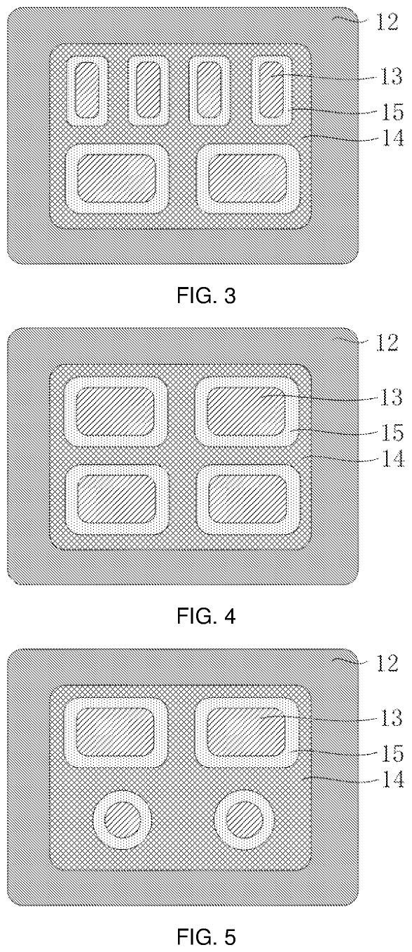

Sizes of cross sections of gates 13 located in different accommodation spaces may be the same or different. In some possible examples, referring to FIG. 2, two gates 13 are provided in the same channel 14, cross-sectional shapes of the two gates 13 are both circular, and sizes of cross sections of the two gates 13 are the same. In some other possible examples, referring to FIG. 3, six gates 13 are provided in the same channel 14, and cross-sectional shapes of the six gates 13 are each a rectangle. The six gates 13 may be divided into two groups. The first group includes four gates 13 located at the upper part, and sizes of cross sections of the four gates 13 are the same. The second group includes two gates 13 located at the lower part, and sizes of cross sections of the two gates 13 are the same. In addition, the sizes of the cross sections of the gates 13 in the first group are different from those of the gates 13 in the second group.

With a plane perpendicular to the extension direction (vertical direction as shown in FIG. 1) of the gate 13 as a cross section, a cross-sectional shape of the gate 13 includes a circle, an ellipse, a square, a rectangle, a trapezoid, or a cross. For the plurality of gates 13 corresponding to the same channel 14, cross-sectional shapes of the gates 13 may be the same or different. Specifically, for the plurality of gates 13 corresponding to the same channel 14, the gates 13 have different cross-sectional shapes; or at least part of the gates 13 have a same cross-sectional shape.

“At least part of the gates 13 have a same cross-sectional shape” means: for the plurality of gates 13 corresponding to the same channel 14, all of the gates 13 have a same cross-sectional shape; or for the plurality of gates 13 corresponding to the same channel 14, some of the gates 13 have a same cross-sectional shape, and the cross-sectional shape of the some of the gates 13 is different from cross-sectional shapes of other gates 13. Through such arrangement, the plurality of gates 13 may be flexibly arranged according to the channel 14 to fully use space of the channel 14.

For example, the same channel 14 corresponds to four gates 13, that is, the channel 14 has four accommodation spaces, and one gate 13 is provided inside each of the accommodation spaces.

In a possible implementation, referring to FIG. 4, cross-sectional shapes of the four gates 13 are the same. For example, the cross-sectional shapes of the four gates 13 are each a rectangle, with rounded corner transitions between sides.

In another possible implementation, three gates 13 of the four gates 13 have a same cross-sectional shape, which is different from a cross-sectional shape of the other gate 13. For example, the cross-sectional shapes of the three gates 13 of the four gates 13 are each a rectangle, and the cross-sectional shape of the other gate 13 is a circle.

In another possible implementation, two gates 13 of the four gates 13 have a same cross-sectional shape, which is different from cross-sectional shapes of the other two gates 13, and the other two gates 13 may have a same cross-sectional shape or different cross-sectional shapes. For example, referring to FIG. 5, the cross-sectional shapes of the two gates 13 of the four gates 13 are each a rectangle, and the cross-sectional shapes of the other two gate 13 are each a circle; or the cross-sectional shapes of the two gates 13 of the four gates 13 are each a rectangle, a cross-sectional shape of another gate 13 is a cross, and a cross-sectional shape of the other gate 13 is a circle.

In an embodiment in which the gates 13 have a same cross-sectional shape, the plurality of gates 13 are arranged in a triangle, a pentagon, a hexagon, or an array. Specifically, that the plurality of gates 13 are arranged in a triangle means that centers of the plurality of gates 13 form a virtual triangle, and the centers of the gates 13 are respectively located at three vertexes of the virtual triangle. For an arrangement manner in which the plurality of gates 13 are arranged in a pentagon or a hexagon, refer to the arrangement manner in which the plurality of gates 13 are arranged in a triangle. Details are not described herein again.

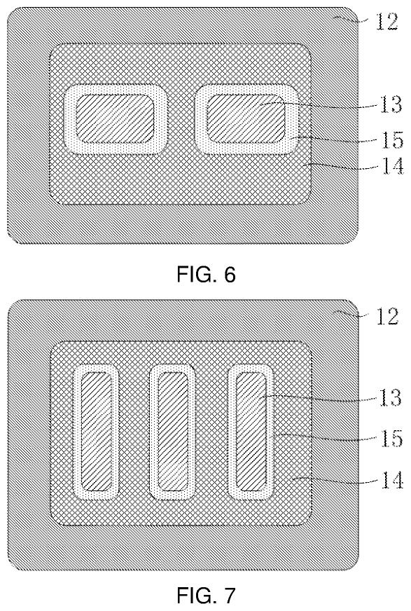

That the plurality of gates 13 are arranged in an array includes: The plurality of gates 13 are arranged in a row, a column, or a matrix. Referring to FIG. 6 and FIG. 7, two gates 13 are arranged in a row. Referring to FIG. 4, four gates 13 are arranged in a square matrix. In another example, the gates 13 may alternatively be arranged in a circle, an ellipse, or in another irregular manner. This is not limited in the present application.

For example, some gates 13 are arranged in a circle, centers of the gates 13 form a virtual circle, and the centers of the gates 13 are equally spaced at the virtual circle. A center of another gate 13 coincides with a circle center of the virtual circle, to improve a quantity of the gates 13. Alternatively, the plurality of gates 13 are arranged in at least two circles, and circle centers of the at least two circles coincide. For example, centers of some gates 13 form a first circle, centers of the other gates 13 form a second circle, a radius of the second circle is less than that of the first circle, and a circle center of the first circle coincides with that of the second circle.

The arrangement manner of the plurality of gates 13 and shapes and sizes of cross-sections of the gates 13 are not limited in the embodiments of the present disclosure, and arrangement of the gates 13 can be optimized by adjusting at least one of the arrangement manner, the shapes, and the sizes of the cross sections of the gates 13, to further fully use space of the channel 14.

Still referring to FIG. 1, the plurality of gates 13 one-to-one correspond to the plurality of accommodation spaces, a first end 16 of each of the gates 13 is located inside an accommodation space corresponding to the gate 13, and a second end 17 of each of the gates 13 is located outside the accommodation space corresponding to the gate 13. That is, the first end 16 of each of the gates 13 is inserted in the channel 14 and the second end 17 of each of the gates 13 is exposed. Through such arrangement, on the one hand, a quantity of gates 13 in a same channel 14 can be increased, increasing contact areas between the gates 13 and the channel 14, and potential at each position of the channel 14 is superposition of respective potential of the plurality of gates 13, increasing a drive current of the transistor. On the other hand, the second end 17 of each of the gates 13 is exposed, and each transistor can be connected to a peripheral circuit by using the second end 17, to drive and control the transistor|.

Specifically, an opening of each of the accommodation spaces is provided at one end of the channel 14 and the second end 17 of each of the gates 13 is exposed outside the accommodation space from the opening corresponding to the gate 13. As shown in FIG. 1, the channel 14 is approximately columnar along the first direction. A plurality of openings are provided at one end of the channel 14 and one-to-one correspond to the plurality of accommodation spaces, and the corresponding opening is in communication with the accommodation space, such that the second end 17 of the gate 13 protrudes from the opening and is exposed outside the accommodation space. The plurality of openings are provided at the same end of the channel 14, such that second ends 17 of the gates 13 are connected together. In this way, the plurality of gates 13 in the same channel 14 are controlled to work simultaneously, and further a control capability of the gates 13 is increased, thereby increasing a drive current.

The channel 14 is made of a semiconductor material such as indium gallium zinc oxide (IGZO), polycrystalline silicon, monocrystalline silicon, amorphous silicon, silicon germanium, or silicon carbide. In some embodiments, the material of the channel 14 is indium gallium zinc oxide and electron mobility of indium gallium zinc oxide is relatively high. This can increase a saturation current of the channel 14 and further increase performance of the transistor.

Still referring to FIG. 1, the dielectric layer 15 is located between the gate 13 and the channel 14, to insulate and isolate the gate 13 and the channel 14. The dielectric layer 15 is made of an insulating material, for example, silicon oxide (SiO₂), silicon nitride (SiN), silicon oxynitride (SiON), or a combination thereof. To ensure performance of insulation between the gate 13 and the channel 14, the insulating material may alternatively be a high dielectric constant material, for example, hafnium oxide (HfO₂), hafnium silicon oxide (HfSiO₂), lanthanum oxide (LaO), zirconium oxide (ZrO₂), zirconium silicon oxide (ZrSiO₂), tantalum oxide (Ta₂O₅), titanium oxide (TiO₂), barium strontium titanium oxide (BaSrTiO₃), barium titanium oxide (BaTiO₃), strontium titanium oxide (SrTiO₃), lithium oxide (Li₂O), aluminum oxide (Al₂O₃), lead scandium tantalum oxide (PbScTaO), lead zinc niobate (PbZnNbO₃), or a combination thereof.

In some possible examples, with a plane perpendicular to the extension direction of the gate 13 as a cross section, a cross-sectional shape of the dielectric layer 15 matches a cross-sectional shape of a corresponding gate 13. Through such arrangement, along a circumferential direction of the gate 13, a thickness of the dielectric layer 15 is uniform, and a distance between a side surface of the gate 13 and a sidewall of the accommodation space is uniform, to ensure uniformity thereof. As shown in FIG. 2, the cross-sectional shape of the gate 13 is a circle, the cross-sectional shape of the dielectric layer 15 is also a circle, and a center of the cross-sectional shape of the gate 13 coincides with a center of the cross-sectional shape of the dielectric layer 15.

Still referring to FIG. 1, the source 11 is provided at one end of the channel 14, the drain 12 is provided at the other end of the channel 14, and the drain 12 and the source 11 are spaced apart. To be specific, the source 11 and the drain 12 are respectively provided at two ends of the channel 14, and the source 11 and the drain 12 are spaced apart, to prevent the source 11 from connecting to the drain 12 due to contact therebetween, to ensure normal work of the transistor.

In some possible embodiments, one of the source 11 and the drain 12 covers one end of the channel 14 and covers a part of the sidewall close to the one end; and the other of the source 11 and the drain 12 covers the other end of the channel 14 and covers a part of the sidewall close to the other end. For example, as shown in FIG. 1, the source 11 covers a lower end of the channel 14 and covers a part of the sidewall close to the lower end and the drain 12 covers an upper end of the channel 14 and covers a part of the sidewall close to the upper end. Through such arrangement, contact areas between the source 11 and the channel 14 and between the drain 12 and the channel 14 are relatively large. This can improve performance of the transistor. In the foregoing embodiment, a notch is provided on the source 11 or the drain 12, and the notch faces the opening of the channel 14, such that the second end 17 of the gate 13 protrudes therethrough.

In some other possible embodiments, one of the source 11 and the drain 12 surrounds and covers a sidewall close to one end of the channel 14, and the other of the source 11 and the drain 12 surrounds and covers a sidewall close to the other end of the channel 14. That is, the source 11 and the drain 12 both face the sidewall of the channel 14. For example, the source 11 surrounds and covers a sidewall close to the lower end of the channel 14 and the drain 12 surrounds and covers a sidewall close to the upper end of the channel 14.

Still referring to FIG. 1, the source 11 is in contact with the channel 14 and the drain 12 is in contact with the channel 14. The channel 14 is made of a semiconductor material, and the source 11 and the drain 12 may be made of a metal material, for example, molybdenum, or may be made of a semiconductor material, for example, polycrystalline silicon.

In some possible embodiments, at least one of the source 11 and the drain 12 is made of a metal material, and metal-semiconductor contact is formed between the source 11 and the channel 14, and/or metal-semiconductor contact is formed between the drain 12 and the channel 14. Specifically, the source 11 is made of a metal material and the drain 12 is made of a semiconductor material; the source 11 is made of a semiconductor material and the drain 12 is made of a metal material; or the source 11 and the drain 12 are each made of a metal material. The source 11 and the drain 12 have a same doping type, which is different from a doping type of the channel 14, to form a metal-oxide-semiconductor field-effect transistor (MOSFET). For example, N-type doping is performed on the source 11 and the drain 12 and P-type doping is performed on the channel 14.

In some other possible embodiments, semiconductor-semiconductor contact is formed both between the source 11 and the channel 14 and between the drain 12 and the channel 14, that is, the source 11 and the drain 12 are each made of a semiconductor material. The source 11, the drain 12, and the channel 14 have a same doping type, to form a junctionless field effect transistor (JLT). For example, N-type doping is performed on all of the source 11, the drain 12, and the channel 14. A size of the junctionless field effect transistor may be further reduced to facilitate forming of a fully depleted channel 14, and an effective length of the channel 14 is further longer. This can suppress a short-channel effect.

Still referring to FIG. 1, the transistor in the embodiments of the present disclosure further includes a conductive layer 20, and the conductive layer 20 is provided on the plurality of gates 13 and is electrically connected to the plurality of gates 13. The plurality of gates 13 are connected together by using the conductive layer 20. In this way, the plurality of gates 13 work simultaneously to increase a drive current. The conductive layer 20 may be made of metal to reduce a contact resistance with the gate 13.

In conclusion, the transistor provided by the embodiments of the present disclosure includes the channel 14, the source 11, the drain 12, the plurality of gates 13, and the dielectric layer 15 located between each of the gates 13 and the channel 14, where the drain 12 and the source 11 are respectively provided at two ends of the channel 14 and are spaced apart along a length direction of the channel 14, the plurality of accommodation spaces are formed inside the channel 14, the first end 16 of each of the gates 13 is located inside one of the accommodation spaces, and the second end 17 of each of the gates 13 is located outside the accommodation space. The plurality of gates 13 are provided inside the same channel 14, increasing a contact area between the gates 13 and the channel 14, and potential at each position of the channel 14 is superposition of respective potential of the plurality of gates 13, such that a drive current of the transistor is increased and a control capability of the gates 13 is improved, thereby improving performance of the transistor.

An embodiment of the present disclosure further provides a memory. The memory may include, for example, a dynamic random access memory (DRAM), a static random access memory (SRAM), a flash memory, an electrically erasable programmable read-only memory (EEPROM), a phase change random access memory (PRAM), a magneto-resistive random access memory (MRAM), or the like.

The memory in this embodiment of the present disclosure includes the foregoing transistor. For example, the memory is a dynamic random access memory and includes a plurality of transistors and a plurality of capacitors. The plurality of transistors are one-to-one electrically connected to the plurality of capacitors, that is, each transistor is electrically connected to one capacitor, and the transistor is used to control on or off of the capacitor. The memory in this embodiment of the present disclosure includes the foregoing transistor, and therefore has at least an advantage that a drive current is large.

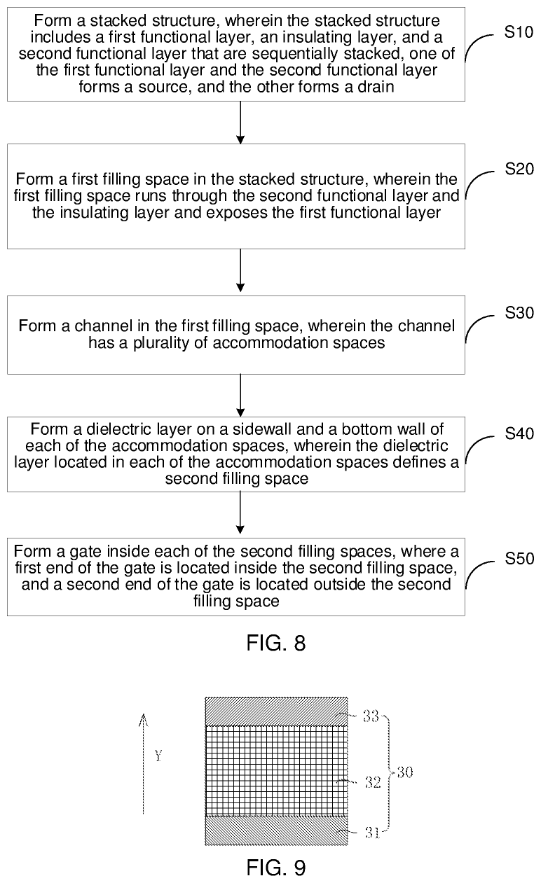

An embodiment of the present disclosure further provides a method of manufacturing a transistor. Referring to FIG. 8, the manufacturing method includes:

Step S10: Form a stacked structure, wherein the stacked structure includes a first functional layer, an insulating layer, and a second functional layer that are sequentially stacked, one of the first functional layer and the second functional layer forms a source, and the other forms a drain.

Referring to FIG. 9, a stacked structure 30 includes a first functional layer 31, an insulating layer 32, and a second functional layer 33. The first functional layer 31, the insulating layer 32, and the second functional layer 33 are sequentially stacked along a first direction, where the first direction is a vertical direction (direction Y) as shown in FIG. 9. One of the first functional layer 31 and the second functional layer 33 forms a source 11 and the other forms a drain 12. For example, the first functional layer 31 forms the source 11 and the second functional layer 33 forms the drain 12. The insulating layer 32 is configured to isolate the source 11 and the drain 12 to ensure normal work of the transistor.

The first functional layer 31, the insulating layer 32, and the second functional layer 33 may be all formed by using a deposition process, where the deposition process includes chemical vapor deposition (CVD), physical vapor deposition (PVD), atomic layer deposition (ALD), or the like.

The insulating layer 32 may be made of an insulating material, for example, silicon oxide, hafnium oxide, zirconium oxide, calcium titanate, barium titanate, or lanthanum aluminate. A material of the first functional layer 31 may be the same as or different from that of the second functional layer 33.

In some possible embodiments, the first functional layer 31 and the second functional layer 33 may be each made of a metal material, for example, molybdenum. The first functional layer 31 and the second functional layer 33 have a same doping type. For example, N-type doping is performed on the first functional layer 31 and the second functional layer 33.

In some other possible embodiments, the first functional layer 31 and the second functional layer 33 may be each made of a semiconductor material, for example, polycrystalline silicon. The first functional layer 31 and the second functional layer 33 have a same doping type. For example, N-type doping is performed on the first functional layer 31 and the second functional layer 33.

Step S20: Form a first filling space in the stacked structure, wherein the first filling space runs through the second functional layer and the insulating layer and exposes the first functional layer.

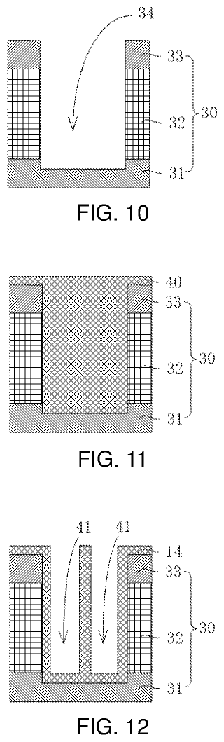

Referring to FIG. 10, the stacked structure 30 is etched, to form the first filling space 34 in the stacked structure 30, and the first filling space 34 runs through the second functional layer 33 and the insulating layer 32 and extends to the inside of the first functional layer 31 to expose the first functional layer 31. That is, a bottom wall of the first filling space 34 is located in the first functional layer 31, but does not run through the first functional layer 31. Through such arrangement, the first functional layer 31 is more exposed in the first filling space 34. Subsequently, when a channel 14 is formed in the first filling space 34, a contact area between the channel 14 and the first functional layer 31 increases, thereby increasing a contact area between the channel 14 and the source 11 or the drain 12.

Step S30: Form the channel in the first filling space, wherein the channel has a plurality of accommodation spaces.

Referring to FIG. 11 and FIG. 12, the channel 14 is located inside the first filling space 34 and is in contact with both of the first functional layer 31 and the second functional layer 33. The channel 14 has the plurality of accommodation spaces 41 and the plurality of accommodation spaces 41 are arranged at intervals. The channel 14 is made of a semiconductor material, for example, indium gallium zinc oxide, polycrystalline silicon, monocrystalline silicon, amorphous silicon, silicon germanium, or silicon carbide. In some embodiments, the material of the channel 14 is indium gallium zinc oxide to improve electron mobility of the channel 14. This can increase a saturation current of the channel 14 and further increase performance of the transistor.

In some possible implementations, forming the channel 14 in the first filling space 34, where the channel 14 has a plurality of accommodation spaces 41 includes:
depositing an initial channel layer 40 in the first filling space 34, where the initial channel layer 40 fully fills the first filling space 34. Referring to FIG. 11, to facilitate deposition of the initial channel layer 40, the initial channel layer 40 may further cover the second functional layer 33. Specifically, the initial channel layer 40 is deposited in the first filling space 34 and on the second functional layer 33, where the initial channel layer 40 fully fills the first filling space 34 and covers a surface of the second functional layer 33 facing away from the first functional layer 31.

After the initial channel layer 40 is deposited, the initial channel layer 40 is etched, to form the plurality of accommodation spaces 41 that are arranged at intervals in the initial channel layer 40, where a remaining initial channel layer 40 forms the channel 14. Specifically, referring to FIG. 11 and FIG. 12, a mask layer is formed on the initial channel layer 40, where the mask layer exposes a part of the initial channel layer 40; and with the mask layer as a mask, wet etching or dry etching is performed to remove the exposed initial channel layer 40, so as to form the accommodation spaces 41 in the initial channel layer 40.

Step S40: Form a dielectric layer on a sidewall and a bottom wall of each of the accommodation spaces, wherein the dielectric layer located in each of the accommodation spaces defines a second filling space.

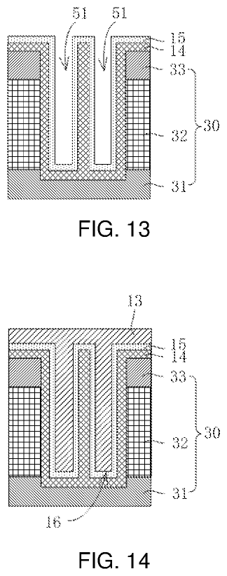

Referring to FIG. 12 and FIG. 13, a dielectric layer 15 covers a sidewall and a bottom wall of the accommodation space 41, and the dielectric layer 15 located inside the accommodation space 41 defines a second filling space 51, to isolate a gate 13 to be subsequently formed inside the second filling space 51 from the channel 14, and ensure that the two are insulated from each other.

The dielectric layer 15 is made of an insulating material, for example, the material of the dielectric layer 15 may be silicon oxide, silicon nitride, silicon oxynitride, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

Step S50: Form a gate inside each of the second filling spaces, wherein a first end of the gate is located inside the second filling space, and a second end of the gate is located outside the second filling space.

Referring to FIG. 13 and FIG. 14, each of gates 13 fills inside one second filling space 51 and extends outside the second filling space 51. For example, each of the gates 13 has a first end 16 and a second end 17 that are opposite, the first end 16 of each of the gates 13 is located inside the second filling space 51, and the second end 17 of the gate 13 is located outside the corresponding second filling space 51. A material of the gate 13 may be metal or alloy, for example, titanium (Ti), titanium nitride (TiN), tungsten (W), or aluminum (Al).

Along a stacked direction (first direction) of the first functional layer 31, the insulating layer 32, and the second functional layer 33, sizes of cross sections of a gate 13 located in one second accommodation space 41 are the same, that is, the gate 13 located in one second accommodation space 41 is designed to have equal cross sections, such that the gate 13 located in the second accommodation space 41 forms a column with consistent top and bottom. The size of the cross section may be an area of the cross section or a diameter of the cross section. Sizes of cross sections of gates 13 located in different second accommodation spaces 41 may be the same or different. This is not limited in this embodiment of the present disclosure.

With a plane parallel to the first functional layer 31 as a cross section, a cross-sectional shape of the gate 13 includes a circle, an ellipse, a square, a rectangle, a trapezoid, or a cross. At least some gates 13 of the plurality of gates 13 have a same cross-sectional shape, which matches cross-sectional shapes of the accommodation spaces 41, and the cross-sectional shape of the gates 13 may be adjusted by adjusting the cross-sectional shapes of the accommodation spaces 41. The accommodation space 41 may be designed according to the channel 14 to fully use space of the channel 14.

In an embodiment in which the gates 13 have a same cross-sectional shape, the plurality of gates 13 are arranged in a triangle, a pentagon, a hexagon, or an array. Specifically, that the plurality of gates 13 are arranged in a triangle means that centers of the plurality of gates 13 form a virtual triangle, and the centers of the gates 13 are respectively located at three vertexes of the virtual triangle. For an arrangement manner in which the plurality of gates 13 are arranged in a pentagon or a hexagon, refer to the arrangement manner in which the plurality of gates 13 are arranged in a triangle. Details are not described herein again.

That the plurality of gates 13 are arranged in an array includes: The plurality of gates 13 are arranged in a row, a column, or a matrix. In another example, the gates 13 may alternatively be arranged in a circle, an ellipse, or in another irregular manner. This is not limited in the present application.

To facilitate manufacturing of the gate 13, in some possible implementations, the gate 13 is deposited in the second filling space 51 and on the dielectric layer 15, and the gate 13 fully fills the second filling space 51 and covers a surface of the dielectric layer 15 facing away from the first functional layer 31. As shown in FIG. 14, the second ends of the gates 13 are integrally formed, such that the gates 13 form an integral structure.

In some possible embodiments, forming the gate 13 inside each of the second filling spaces 51, where a first end 16 of the gate 13 is located inside the second filling space 51, and a second end of the gate 13 is located outside the second filling space 51 further includes: forming a conductive layer 20 on the gate 13, where the conductive layer 20 is electrically connected to the second ends of the gates 13. The plurality of gates 13 can be connected together by providing the conductive layer 20. In this way, the plurality of gates 13 work simultaneously to increase a drive current. The conductive layer 20 may be made of metal to reduce a contact resistance with the gate 13. In the embodiment in which the second ends of the gates 13 are integrally formed, the conductive layer 20 may be manufactured on the second ends of the gates 13, or the second ends of the gates 13 may be used as the conductive layer 20.

In conclusion, in the method of manufacturing a transistor provided in the embodiments of the present disclosure, the first filling space 34 is formed in the stacked structure 30, and the channel 14 is formed inside the first filling space 34, where the channel 14 has the plurality of accommodation spaces 41; and then the gate 13 is formed inside each of the accommodation spaces 41, and the dielectric layer 15 located between the gate 13 and the channel 14 is formed. In this way, a quantity of gates 13 inside the same channel 14 is increased, increasing a contact area between the gates 13 and the channel 14. In addition, potential at each position of the channel 14 is superposition of respective potential of the plurality of gates 13. Therefore, a drive current of the transistor is increased and a control capability of the gates 13 is improved, thereby improving performance of the transistor.

The embodiments or implementations of this specification are described in a progressive manner, and each embodiment focuses on differences from other embodiments. The same or similar parts between the embodiments may refer to each other. In the descriptions of this specification, a description with reference to the term “one implementation”, “some implementations”, “an exemplary implementation”, “an example”, “a specific example”, “some examples”, or the like means that a specific feature, structure, material, or characteristic described in combination with the implementation(s) or example(s) is included in at least one implementation or example of the present disclosure. In this specification, the schematic expression of the above terms does not necessarily refer to the same implementation or example. Moreover, the described specific feature, structure, material or characteristic may be combined in an appropriate manner in any one or more implementations or examples.

Finally, it should be noted that the foregoing embodiments are used only to explain the technical solutions of the present disclosure, but are not intended to limit the present disclosure. Although the present disclosure has been described in detail with reference to the foregoing embodiments, those of ordinary skill in the art should understand that they can still modify the technical solutions described in the foregoing embodiments, or make equivalent substitutions on some or all technical features therein. The modifications or substitutions do not make the essence of the corresponding technical solutions deviate from the scope of the technical solutions of the embodiments of the present disclosure.

1. A transistor, comprising:
a channel, wherein a plurality of accommodation spaces are formed therein;
a plurality of gates, wherein the plurality of gates have a same extension direction and each have a first end and a second end that are opposite, the first end of the gate is located inside one of the accommodation spaces, and the second end of the gate is located outside the corresponding accommodation space;
a dielectric layer, located between the gate and the channel, insulating and isolating the gate and the channel;
a source, provided at one end of the channel; and
a drain, provided at the other end of the channel, wherein the drain and the source are spaced apart.

2. The transistor according to claim 1, wherein an opening of each of the accommodation spaces is provided at one end of the channel, and the second end of the gate is exposed outside the accommodation space from the opening corresponding to the gate.

3. The transistor according to claim 2, wherein one of the source and the drain covers one end of the channel and covers a part of a sidewall close to the one end; and
the other of the source and the drain covers the other end of the channel and covers a part of the sidewall close to the other end.

4. The transistor according to claim 1, wherein the transistor further comprises a conductive layer provided on the plurality of gates, and the conductive layer is electrically connected to the plurality of gates.

5. The transistor according to claim 1, wherein with a plane perpendicular to the extension direction of the gate as a cross section, a cross-sectional shape of the gate is a circle, an ellipse, a square, a rectangle, a trapezoid, or a cross.

6. The transistor according to claim 5, wherein at least part of the gates have a same cross-sectional shape.

7. The transistor according to claim 6, wherein the gates have a same cross-sectional shape, and the plurality of gates are arranged in a triangle, a pentagon, a hexagon, or an array.

8. The transistor according to claim 6, wherein with the plane perpendicular to the extension direction of the gate as the cross section, a cross-sectional shape of the dielectric layer matches a cross-sectional shape of the corresponding gate.

9. The transistor according to claim 1, wherein a metal-semiconductor contact is formed between the source and the channel, and/or the metal-semiconductor contact is formed between the drain and the channel.

10. A memory, comprising the transistor according to claim 1.

11. A method of manufacturing a transistor, comprising:
forming a stacked structure, wherein the stacked structure comprises a first functional layer, an insulating layer, and a second functional layer that are sequentially stacked, one of the first functional layer and the second functional layer forms a source, and the other forms a drain;
forming a first filling space in the stacked structure, wherein the first filling space runs through the second functional layer and the insulating layer, and exposes the first functional layer;
forming a channel inside the first filling space, wherein the channel has a plurality of accommodation spaces;
forming a dielectric layer on a sidewall and a bottom wall of each of the accommodation spaces, wherein the dielectric layer located in each of the accommodation spaces defines a second filling space; and
forming a gate inside each of the second filling spaces, wherein a first end of the gate is located inside the second filling space, and a second end of the gate is located outside the second filling space.

12. The method of manufacturing according to claim 11, wherein a bottom wall of the first filling space is located in the first functional layer.

13. The method of manufacturing according to claim 11, wherein the forming a channel inside the first filling space, wherein the channel has a plurality of accommodation spaces comprises:
depositing an initial channel layer inside the first filling space, wherein the initial channel layer fully fills the first filling space; and
etching the initial channel layer, to form the plurality of accommodation spaces that are arranged at intervals in the initial channel layer, wherein a remaining initial channel layer forms the channel.

14. The method of manufacturing according to claim 11, wherein the forming a gate inside each of the second filling spaces, wherein a first end of the gate is located inside the second filling space, and a second end of the gate is located outside the second filling space further comprises:
forming a conductive layer on the gate, wherein the conductive layer is electrically connected to the second end of each of the gates.

15. The method of manufacturing according to claim 11, wherein with a plane parallel to the first functional layer as a cross section, at least part of the gates have a same cross-sectional shape.
